(19) United States
(12) Patent Application Publication
(10) Pub. No.: US 2023/0014118 A1
(43) Pub. Date: Jan. 19, 2023

(54) APPARATUS FOR SIGNAL EXCHANGE BETWEEN CONTROLLER AND FIELD DEVICES

(71) Applicant: Phoenix Contact GmbH & Co. KG, Blomberg (DE)

(72) Inventors: Elmar Schaper, Luegde (DE); Karsten Meyer-Graefe, Schloss Holte-Stukenbrock (DE); Ruediger Harnasch, Paderborn (DE)

(21) Appl. No.: 17/786,548

(22) PCT Filed: Dec. 10, 2020
(86) PCT No.: PCT/EP2020/085555

§ 371 Date: Jun. 17, 2022

(30) Foreign Application Priority Data
Dec. 19, 2019 (DE) 10 2019 135 089.1

(51) Int. Cl. H05K 7/14

(52) U.S. Cl. CPC H05K 7/1479; H05K 7/1465; H05K 7/1474; H05K 7/1477

(57) ABSTRACT

A technique for exchanging signals between a control system (200) and at least two field devices (300) is described. One device aspect of the technique comprises a base (102) that comprises a control interface (104) and at least two slots (106). The control interface (104) is configured to connect (108.1) to at least two electrical line channels (108) of the control system (200) and the at least two slots (106) are each configured to detachably mechanically connect (106.1) to a module (110) and to pass (106.2) at least one of the line channels (108) to the respective module (110). Furthermore, the device comprises one or more modules (110), each of which comprises a base-side slot interface (112) and a field-side input and/or output interface, I/O interface, (114) different from the slot interface (112), wherein the slot interface (112) is configured for a detachable mechanical and electrical connection to one of the slots (106) of the base (102), and the I/O interface (114) is configured for a connection (116.1) to signal lines (116) of one of the field devices (300).

### CROSS-REFERENCE TO PRIOR APPLICATIONS

This application is a U.S. National Phase application under 35 U.S.C. § 371 of International Application No. PCT/EP2020/085555, filed on Dec. 10, 2020, and claims benefit to German Patent Application No. DE 10 2019 135 089.1, filed on Dec. 19, 2019. The International Application was published in German on Jun. 24, 2021 as WO/2021/122318 under PCT Article 21(2).

### FIELD

The invention relates to a device for exchanging signals between a control system and at least two field devices.

### BACKGROUND

Control systems, in particular programmable logic controllers (PLCs), are connectable to logic modules in order to acquire or output a wide variety of field-side signal forms. This is also referred to as signal conditioning or more generally as “marshalling”. Document U.S. Pat. No. 9,971,727 describes an interposer system for processing input and/or output signals transmitted between a field device and a control system. The system comprises a base (or carrier). Modules comprising signal processing circuitry are plugged onto the base. The base comprises both a field-side connector and a controller-side connector.

While the conventional interposer system is advantageous for module replacement, the wiring of the field devices on the base, which remains unchanged when a module is replaced, may result in either the use of an existing signal line that is unsuitable for the changed signal form (for example, one that is susceptible to interference) or the need to reassemble the field-side connection on the base. This applies accordingly to the connection on the control side.

### SUMMARY

IN AN EMBODIMENT, THE PRESENT INVENTION PROVIDES A DEVICE FOR EXCHANGING SIGNALS BETWEEN A CONTROL SYSTEM AND AT LEAST TWO FIELD DEVICES, COMPRISING: A BASE COMPRISING A CONTROL INTERFACE AND AT LEAST TWO SLOTS, THE CONTROL INTERFACE BEING CONFIGURED TO CONNECT TO AT LEAST TWO ELECTRICAL LINE CHANNELS OF THE CONTROL SYSTEM, AND EACH SLOT OF THE AT LEAST TWO SLOTS BEING CONFIGURED TO DETACHABLY MECHANICALLY CONNECT TO A MODULE AND TO PASS AT LEAST ONE OF THE LINE CHANNELS OF THE AT LEAST TWO ELECTRICAL LINE CHANNELS TO A RESPECTIVE MODULE; AND ONE OR MORE MODULES, EACH MODULE OF THE ONE OR MORE MODULES COMPRISING A BASE-SIDE SLOT INTERFACE AND A FIELD-SIDE INPUT AND/OR OUTPUT INTERFACE, I/O INTERFACE, DIFFERENT FROM THE SLOT INTERFACE, WHEREIN THE SLOT INTERFACE IS CONFIGURED TO MECHANICALLY AND ELECTRICALLY DETACHABLY CONNECT TO ONE SLOT OF THE SLOTS OF THE BASE, AND WHEREIN THE I/O INTERFACE IS CONFIGURED TO CONNECT TO SIGNAL LINES OF AT LEAST ONE FIELD DEVICE OF THE AT LEAST TWO FIELD DEVICES.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 is a schematic perspective view of a device for exchanging signals between a control system and at least two field devices according to a first embodiment;

FIG. 2 is a schematic perspective view of a device for exchanging signals between a control system and at least two field devices according to a second embodiment;

FIG. 3 is a schematic perspective view of a device for exchanging signals between a control system and at least two field devices according to a third embodiment; and

FIG. 4 is a schematic perspective view of a device for exchanging signals between a control system and at least two field devices according to a fourth embodiment.

### DETAILED DESCRIPTION

In an embodiment, the present invention provides a base in which individual modules may be exchanged independently of one another and during operation, thus enabling a simplified adaptation or an increased variability in connection options for connecting to field devices or a control system.

According to a first aspect, a device for exchanging signals between a control system and at least two field devices comprises a base and one or more modules. The base comprises a control interface and at least two slots. The control interface is configured to connect to at least two electrical line channels of the control system. Each of the at least two slots is configured to detachably (or reversibly or releasably) mechanically connect (e.g., attach) a module and pass (or electrically connect) at least one of the line channels to the respective module. The module, or each of the plurality of modules, comprises a base-side slot interface and a field-side input and/or output interface (I/O interface) that is different from the slot interface. The slot interface is configured for detachable mechanical and electrical connection to one of the slots of the base. The I/O interface is configured to connect to signal lines of one of the field devices.

Embodiments may allow individual modules to be changed (or exchanged or replaced) on the base, for example, independently and/or during operation of the control system, the device, and/or the other modules. By changing individual modules that comprise the I/O interface that is different from the slot interface, the connections for connecting to field devices (i.e., the I/O interfaces for connecting to the signal lines of the field devices) and/or the connection for connecting to the control system (i.e., the control interface for connecting to the line channels) may be adaptable or variable, for example, adaptable in response to a replacement of individual field devices and/or their wiring (i.e., their signal lines).

Embodiments of the module or the modules (preferably signal processing modules) may initially be arranged in the slots of an embodiment of the base. To improve adaptability or variability, the module or each of the modules may have at least two interfaces, in particular the slot interface and the I/O interface, which are configured to establish an electrical connection with the control system (for example, a controller system or central control system) and with the respective field device, respectively. For example, one interface (namely the slot interface) for connecting to the slot and another interface (namely the I/O interface, preferably a plug-in connector half or plug connection) for wiring to the field device are provided on the respective module.

The modules may be configured to electrically connect to or disconnect from the respective slot of the base and/or to establish or release a communication channel with the control system via the respective line channel of the control system by means of their slot interface during operation of the control system.

The control system may be a (e.g., industrial) process control system. The base may also be referred to as a base board or interposer. The field devices may comprise sensors and/or actuators.

Connecting and disconnecting the module (e.g., on the field-side to and from the respective field device, or on the control-side to and from the control system, respectively) may comprise connecting and disconnecting the signal lines from the respective I/O interface, for example, connecting and disconnecting a plug provided for the respective module to the respective I/O interface (preferably an I/O socket).

Embodiments may allow easy adaptation of the module, or one of the modules, on the base. Alternatively or additionally, a variable connection of the respective field device to any line channel of the control system may be enabled. For example, by changing a single module, the respective I/O interface may comprise a plug-in connector half specific to the field device in question.

Any interface referred to herein may be implemented using a terminal or plug-in connector half, such as a socket, plug, or hermaphroditic plug-in connector half. For example, the I/O interface may comprise a male connector and/or a female connector.

The base may be a common one for the at least two slots. The base may have a backplane for passing the at least one of the line channels to the respective module.

The control interface of the base may comprise a plug-in connector half, preferably a socket or a plug. The plug-in connector half of the control interface may be configured to connect the at least two electrical line channels of the control system.

All line channels may be connectable to the base by means of a single plug-in connector half (preferably the control interface). The plug-in connector half may be configured for plug-in connection with a complementary plug-in connector half. The complementary plug-in connector half may comprise the at least two line channels in a mechanically coherent manner (or in a single piece).

The I/O interface of one or each module may comprise a plug-in connector half, preferably a socket or plug, for connecting the signal lines of the respective field device.

The device may further comprise the signal lines of a plurality of field devices.

The signal lines of each of the plurality of field devices may comprise a (preferably mechanically connected) plug-in connector half. The plug-in connector half of one field device may be detachably connected or connectable to the I/O interface of the respective module for connecting to the signal lines of the respective field device.

Alternatively or additionally, the signal lines of the plurality of field devices or a subset of the field devices may comprise a cross-module (or modules-spanning) plug-in connector half. The cross-module plug-in connector half may be detachably connected or connectable (preferably simultaneously) to the I/O interfaces of the respective modules for connecting to the signal lines of the plurality of field devices. The slot interfaces of the respective modules may be mechanically and electrically connected to adjacent slots of the base. In other words, the plurality of field devices or the subset of field devices may be connected to modules arranged (preferably directly) adjacent to each other on the base by means of the cross-module plug-in connector half.

The cross-module plug-in connector half may be referred to as the common plug-in connector half of the plurality of field devices. The cross-module plug-in connector half may enable quick installation of a group of field devices. For example, the plurality of field devices or the subset of field devices or the group of field devices whose signal lines comprise the cross-module plug-in connector half may form a functional group, such as an actuator and a sensor for controlling a controlled variable influenced by the actuator according to an actual value of the controlled variable acquired by the sensor.

The device may further comprise the signal line or signal lines of one of the field devices. The signal line or lines of one of the field devices may comprise a cross-module plug-in connector half that is (preferably simultaneously) detachably connected or connectable to the I/O interfaces of at least two modules for connecting the signal line or lines of the one of the field devices to the plurality of modules. The slot interfaces of the at least two modules may be mechanically and electrically connected to adjacent slots of the base. In other words, the one of the field devices may be connected to modules arranged adjacent (preferably directly) on the base by means of the cross-module plug-in connector half.

The cross-module plug-in connector half may straddle (or extend along) a plurality of modules (preferably adjacent on the base). The common plug-in connector half may also be referred to as a bridge. The cross-module plug-in connector half may be electrically connected to one of the signal lines to one of the field devices. For example, the signal line electrically conductively connected to the cross-module plug-in connector half may comprise a field connector at an end of the signal line opposite the cross-module plug-in connector half, which may be electrically connected or connectable to the one field device.

By connecting one field device to a plurality of (for example two) modules by means of the plug-in connector half that spans the modules, the plurality of modules may enable redundant and thus fail-safe communication between the control system and the one field device. For example, the control system is configured to continue communication with one field device via the other module in the event of a failure of communication (preferably in the case of redundancy or in the event of an error) with the one field device via one of the modules.

The device may further comprise the signal lines of at least one field device. The signal lines of the field device may comprise a plug-in connector half that is detachably connected or connectable (preferably directly) to one of the control interfaces of the base for connecting the signal lines of the respective field device.

The signal lines of at least one field device may comprise a plug-in connector half that is detachably connected or connectable to one of the control interfaces (for example, each of the control interfaces) of the base for connecting the signal lines of the respective field device without the interposition of a module. For example, a plug or adapter for connecting the signal lines of one of the field devices may be arranged (preferably detachably connected) at at least one slot instead of a module.

All or a subset of the I/O interfaces may be identical in construction. Alternatively or additionally, all the ports or a subset of the ports of the signal lines may be identical in construction.

Each of the I/O interface and the slot interface of each module may be spatially separated from each other. The interfaces may be provided on different housing sides of a housing of the respective module, e.g., such that one of the interfaces is arranged on one housing side and another one of the interfaces is arranged on another housing side. The housing side for the connection (preferably plug connection) of the respective field device may be accessible from the outside (for example for connection and disconnection operations) when the module is plugged into the respective slot.

The I/O interface and the slot interface of each module may be arranged on different edges of the respective module and/or different sides of a module housing of the respective module. The I/O interface and the slot interface may be arranged on adjacent or opposite sides or edges of the respective module.

The I/O interface and the slot interface may each define a plug-in direction in which the signal lines can be connected or the module can be mechanically connectable. The plug-in direction of the I/O interface and the plug-in direction of the slot interface may be parallel or transverse to each other, preferably perpendicular to each other.

Preferably, the interface of the base may comprise a mechanical interface for fastening, for example locking, the respective module. Alternatively or additionally, the module housing may comprise a mechanical interface for fastening, for example locking, the respective module to the base.

The base may be configured to pass different line channels of the control system at different slots.

The feed-through (or the pass) of the line channels may be a 1-to-1 connection from the control system to the module. The feed-through may comprise a back-wiring or so-called “backplane” on the base.

The base may be configured to pass through one of the line channels of the control system at each of the slots. The base may be configured to pass exactly one of the at least two electrical line channels uniquely through each of the slots.

The base may be configured to pass the line channels to the respective module without its own signal processing and/or with a linear signal response (or signal transfer function). The base may be configured to provide the line channels to the individual modules without its own and/or without non-linear signal processing or without data processing.

The line channels passed (or passed through) to the respective module may comprise a (preferably serial and/or digital) communication between the control system and the module. The base may be configured to pass the communication (through) to the individual modules without its own signal processing and/or its own data processing.

Each of the modules may be configured to be in signal line connection with at least one of the field devices by means of the signal lines. Each field device may be in signal line connection with an associated module via separate signal lines. The signal line connection may comprise input signals from the respective field device and/or output signals to the respective field device. The signal line may comprise wiring between the I/O interface and the respective field device.

The field devices may be connected to the control system by means of the I/O interface on the respective module via the base. The sensors may output measurement signals, analysis signals and/or alarm signals to the respective module by means of the signal line. The respective module may acquire the (e.g., measured) signals and send them as data to the control system via the relevant line channel.

Alternatively or additionally, the actuators may comprise switches and/or controlling elements. The respective module may receive control signals from the control system via the forwarded line channel and output corresponding (for example actuator-specific) control signals to the actuator via the I/O interface. For example, based on the signals from the field devices, the modules may send measurement data to the control system via the relevant line channels, preferably continuously (for example periodically or at specific time intervals) or event-driven (for example in response to an interrogation instruction from the control system). Alternatively or additionally, the modules may receive control data for the respective actuators via the respective line channels. Preferably, the modules do not exchange the acquired signals directly with each other, but send them to the control system, for example to exchange the acquired signals at an application level or process level of the control system.

The module or one or each of the modules (or the corresponding slot interface) may be insertable into any of the slots of the module.

The at least two slots of the base may be configured to mechanically connect and/or disconnect at least two modules to the base independently of each other.

The modules may be individually accessible, individually connectable (for example, individually insertable and/or individually lockable), and/or individually releasable in their respective slots. For example, each slot may comprise an independent locking mechanism and/or longitudinal guide for releasable mechanical connection to one of the modules. Alternatively or additionally, the at least two modules may be contiguous and/or insertable into adjacent slots of the module. For example, at least two modules may be insertable into their respective slots simultaneously (i.e., en bloc).

The module, or at least one or each of the modules, may comprise a signal processing unit configured to output and/or acquire signals at the I/O interface, receive and/or transmit signals at the slot interface, and process the received signals into the output signals and/or process the acquired signals into the transmitted signals.

The module or each of the modules may comprise an electronic signal processing unit which (for example in automation or production engineering) is connected or connectable to the control system by means of the slot interface, the feed-through (or pass) of the relevant line channel and via the control interface. The modules may be configured to provide functions at a field layer, at a physical layer, and/or at the lowest layer in a protocol stack or a hierarchical layer model (e.g., in the OSI layer model) of a field bus (for example, in automation or production engineering).

The signal processing unit may comprise a signal amplifier, an analog-to-digital converter, a digital-to-analog converter, a galvanic isolation (for example, an opto-coupler), and/or a solid-state relay (for example, for switching a circuit in accordance with a logic control signal from the control system).

The or each module may comprise its own module housing. Preferably, the respective signal processing unit may be arranged and/or implemented in the respective module housing.

The device may further comprise a device housing. The device housing may have the base arranged therein. The module or modules may be arranged or arrangeable in the device housing in the state connected to the base. Optionally, the I/O interface may be accessible through an opening in the device housing from outside the device housing in the state of the respective module being connected to the base.

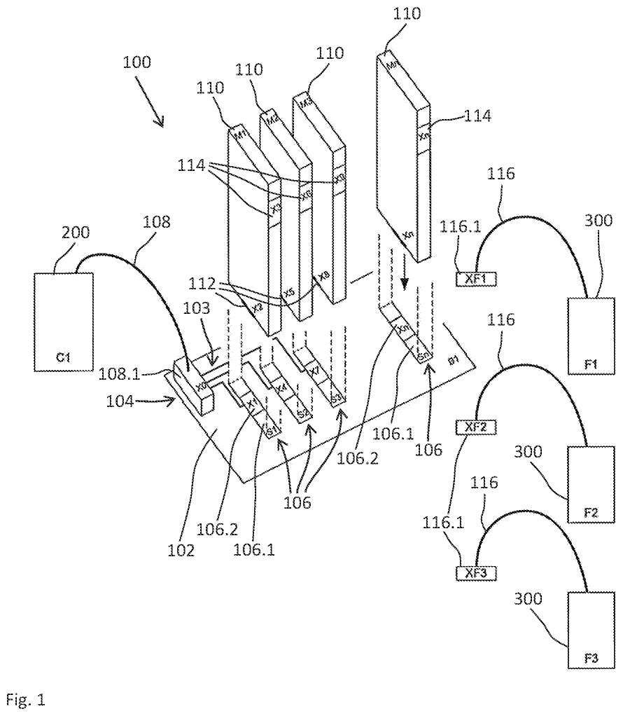

FIG. 1 shows a schematic perspective view of a first embodiment of a device, generally designated by reference numeral 100, for exchanging signals between a control system and at least two field devices. The device 100 comprises a base 102 that includes a control interface 104 and at least two slots 106. The control interface 104 is configured for a connection 108.1 with at least two electrical line channels 108 of the control system 200. Each of the at least two slots 106 is configured to detachably (or reversibly or releasably) mechanically connect 106.1 with a module 110 and to pass 106.2 (or electrically connect) at least one of the line channels 108 to the respective module 110.

Furthermore, the device 100 comprises one or more modules 110, each of which comprises a slot interface 112 towards the base (i.e., a base-side slot interface 112) and an input and/or output interface 114 (TO interface, also I/O interface), which is different from the slot interface 112, towards the field (i.e., a field-side I/O interface 114). The slot interface 112 is configured for a detachable mechanical and electrical connection to one of the slots 106 of the base 102. The I/O interface 114 is configured to connect 116.1 to signal lines 116 of one of the field devices 300.

The base 102 may also be referred to in technical terms as a base board or motherboard, or may be designated “B1” in the figures. The control system 200 may be a microcontroller or a programmable logic controller (PLC). The control system 200 may be designated “Cl” in the figures. Each field device 300 may comprise at least one sensor and/or at least one actuator. The field devices 300 may be designated “Fj” in the figures for the j-th field device 300. The field devices 300 may be collectively referred to as a field.

A module “M1” of the modules 110 is plugged into the slot 106 designated “S1”. The slot 106 for the module “M1” comprises a mechanical contact surface configured for (preferably non-destructive) detachable mechanical connection 106.1 to the respective module 110. For example, the slot 106 comprises a guide perpendicular to a plane of the base 102 (preferably at corners of the contact surface “S1”) for longitudinal guidance of the module 110 and/or a latch for releasable attachment of the module 110.

On the mechanical contact surface “S1” or within the contact surface “S1” is a base-side plug-in connector half “X1” for passing at least one of the line channels 108 to the module 110 designated “M1”.

The module 110 designated “M1” comprises a module-side plug-in connector half “X2” at the slot interface 112. The module-side plug-in connector half “X2” is configured to contact the base-side plug-in connector half “X1” for feed-through 106.2 when the respective module 110 is mechanically secured in the corresponding slot 106 designated “S1”.

Preferably, the slot interface 112 is arranged on a first edge or first side of the module 110, and the field-side I/O interface 114 is arranged on a second edge or second side of the same module 110 that is different from the first edge or first side. For example, the first edge and the second edge or the first side and the second side are opposite each other on the module 110. Alternatively or additionally, the first edge and the second edge or the first side and the second side share a corner of the module 110, meet at a corner of the module 110, or are adjacent to each other.

The base-side slot interface 112 may also be referred to as the base port. The field-side I/O interface 114 may also be referred to as a field port. The field-side I/O interface 114 may comprise a socket (also: field socket).

On the module 110 designated “M1”, the field-side I/O interface 114 is designated “X3”. A connector 116.1 (for example, designated XF1) of the respective field device 300 (for example, designated F1) may be connected to the field-side I/O interface 114 (for example, plugged into the I/O interface 114). The field device 300 may be a sensor or actuator.

The connection 116.1 of the signal lines 116 of the respective field device 300 may comprise a plug. The connection 116.1 of the signal lines 116 of the respective field device 300 may be referred to as a field connector.

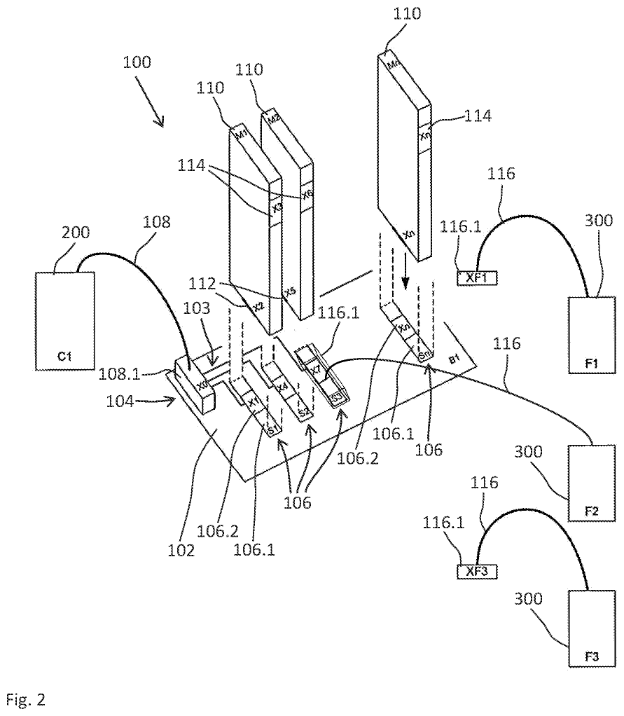

Preferably, all I/O interfaces 114 (for example, all field connectors and/or all I/O interfaces 114 designated “X3”, “X6”, “X9”, etc. in FIG. 1 or 2) or all connections 116.1 (for example, all field connectors and/or all connections designated “XF1” to “XF3” in FIG. 1) are identical in construction. In a fault case or a redundancy case, a plug 116.1 (for example, the plug “XF1”) may also be plugged into the I/O interface 114 of another module 110.

The control system 200 is configured to read or write (for example, twice) to each of the corresponding two or more modules connected to the same field device 300, particularly in the event of a fault and/or redundancy.

Embodiments of the device allow variable adaptation in case of service, whereby another channel may be selected than the one originally used. In the case of a dual (or redundant) design and equal functional units (e.g. for a digital output “DO”) of two or more modules 110, in the event of failure of an output, operability may be achieved with another output of another module 110 by repositioning the plug XFj.

Furthermore, the control system 200 may be configured to apply two different program flows (or functions) to, e.g., 2 digital outputs (DO1 and DO2) to be programmed and/or controlled. Depending on the need, one or the other flow (or function) may be provided to the actuator by changing the plugs from DO1 to DO2.

Moreover, it is possible to further modularize a module 110 by using signal processing and/or conductor devices between the slot interface 112 and the I/O interface 114.

In embodiments of the device 100, not all field devices 300 need to be connected to the control system 200 via plugged modules 110. For example, the central connector X1 for the pass (or feed-through) 106.2 at the slot 106 may be used to directly contact the field connector 116.1 (or field plug, e.g., XF1) thereon. This allows reducing hardware complexity. This may be done for simple applications without additional galvanic isolation and/or for small signals that can be generated directly from the control system, for example.

FIG. 2 schematically illustrates a perspective view of a second embodiment of the device 100. The second embodiment may be implementable by itself or in further development of the first embodiment.

In case no signal processing (for example no signal conversion) is necessary, the corresponding module 110 (for example the module “M1” or, in the example of FIG. 2, the module “M3”) may be omitted. In that case, the corresponding field device 300 (for example, the sensor and/or the actuator) may be plugged with its connector or plug 116.1 (for example, with the plug XF1 or XF3) directly onto the base 102, for example, onto the corresponding slot (for example, the slot “S1” or “S3”) on X1.

Preferably, all I/O interfaces 114 (for example, all field jacks and/or all I/O interfaces 114 designated “X3”, “X6”, “X9”, etc. in FIG. 1 or 2) and all slots 106 are identical in construction with respect to their contacts (or contacting) for the pass (or feed-through) 106.2 (for example, the plug-in connector halves “X1”, “X4”, “X7”, etc.), for example, so that the connection 116.1 is optionally electrically connectable to one of the modules 110 or one of the slots 106.

The modules 110 may be signal processing modules. The modules 110 are initially arranged, for example to the extent necessary for signal processing, at slots of a base.

In any embodiment, to increase variability, it may be provided that at least one module 110, preferably each module 110, has at least two interfaces 112 and 114 to establish a connection with a control system 200 (for example, a controller system) and with the respective field device 300, respectively. In this regard, a slot interface 112 is provided for connection to the slot 106 and another I/O interface 114 is provided for a connection 116.1 (for example, a plug connection) for the signal lines 116 (for example, for wiring) to the field device 300.

Each module 110 may be enclosed in a housing. The interfaces 112 and 114 are preferably arranged on different sides of the housing, for example so that one interface 112 is arranged on one side of the housing and the other interface 114 is arranged on another side of the housing. The latter side is preferably accessible for connection 116.1 (for example a plug connection), in particular from the outside for connection and disconnection operations, for example when the module is plugged into the slot 106.

Connecting and disconnecting the module 110 (for example, field-side and/or control-side) is preferably accomplished by connecting and disconnecting a plug provided for the respective module 110 (for example, field-side connector 116.1 or base-side feed-through 106.2) to the respective interface 114 or 112.

Embodiments of the device 100 may have the advantage of allowing easy adaptation or replacement of a module 110 on a base 102. Alternatively or further, variable adaptation of the field-side may be possible on any or a single I/O channel or line channel.

This implementation, which is open and pluggable towards the field, may resemble a wiring harness. Thus, exchanging the wiring harness allows an easy migration and/or adaptability to different requirements.

Embodiments of the device 100 may implement the I/O interface 114 on at least one module 110, while the other modules may be connectable to the control system 200 and the field devices 300, for example, in accordance with document U.S. Pat. No. 9,971,727. This provides further freedom for a modular design and individual adaptability of the system.

Each embodiment of the device 100 may further comprise a mechanical connection between the I/O interface 114 and the connector 116.1. For example, individual sockets or plugs may be provided with a mechanical connection for at least one of the modules 110, which may be arranged on a frame or housing of the respective module 110. The mechanical connection may comprise, for example, a latch and/or a swivel device configured to swivel the connector 116.1 (for example, the plugs) onto and/or off the I/O interface 114. This may simplify handling when connecting or disconnecting the field devices 300.

Alternatively or additionally, embodiments of the device 100 may further comprise a mechanical connection between the slot 106 and the slot interface 112. For example, individual sockets or plugs with mechanical connection may be provided for at least one of the modules 110, which may be arranged on a frame or housing of the base 102. The mechanical connection may comprise, for example, a latch and/or a pivot device configured to pivot the respective module 110 (for example, its plug for the slot interface 112) onto and/or off the slot 106. This may simplify handling when replacing (preferably connecting or disconnecting) the modules 110.

Furthermore, the frame of the base 102 may comprise a slot and/or compartment at each slot 106 configured to respectively allow a module 110 to be fed more easily or in a straight line to the respective slot 106 of the base 102.

The base 102 may include a rear pathways 103 (also referred to as a backplane) for passing, to each of the slots 106, a respective one or plurality of other line channels 108 of the control interface 104.

In any embodiment, a mechanical interface for securing the connector 116.1, such as a latch, may be provided on the I/O interface 114 of one or each module 110.

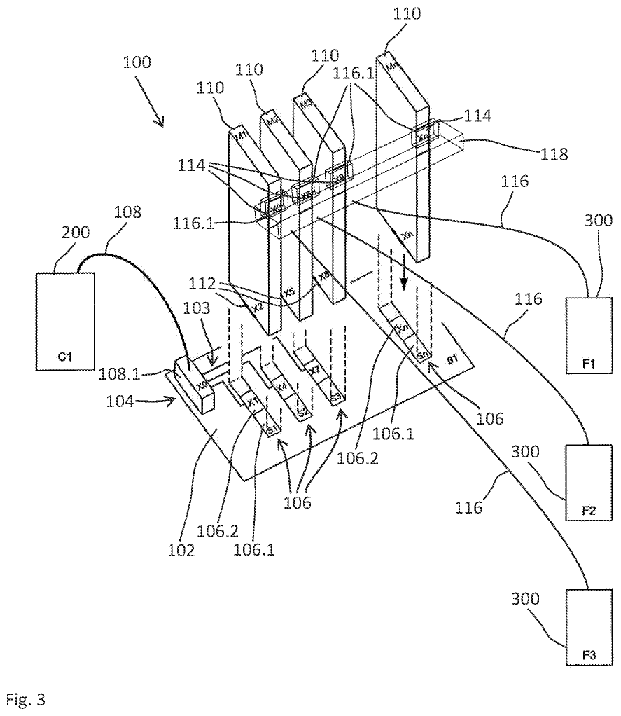

FIG. 3 schematically shows a perspective view of a third embodiment of the device 100. The third embodiment may be realizable by itself or in further development of the first and/or second embodiment.

The signal lines 116 of two, three, or plurality of field devices 300 comprise a plug-in connector half 118 that spans multiple modules, preferably a common plug-in connector half 118 for the two, three, or plurality of field devices 300. The plug-in connector half 118 is simultaneously detachably connected or connectable to the I/O interfaces 114 of two, three, or plurality of modules 110 for connecting 116.1 the signal lines 116 of the respective field devices 300.

Preferably, the slot interfaces 112 of the respective modules 110 are mechanically and electrically connected to adjacent slots 106 of the base 102. That is, the cross-module (or modules-spanning) plug-in connector half 118 may overlap directly adjacent modules on the base 102.

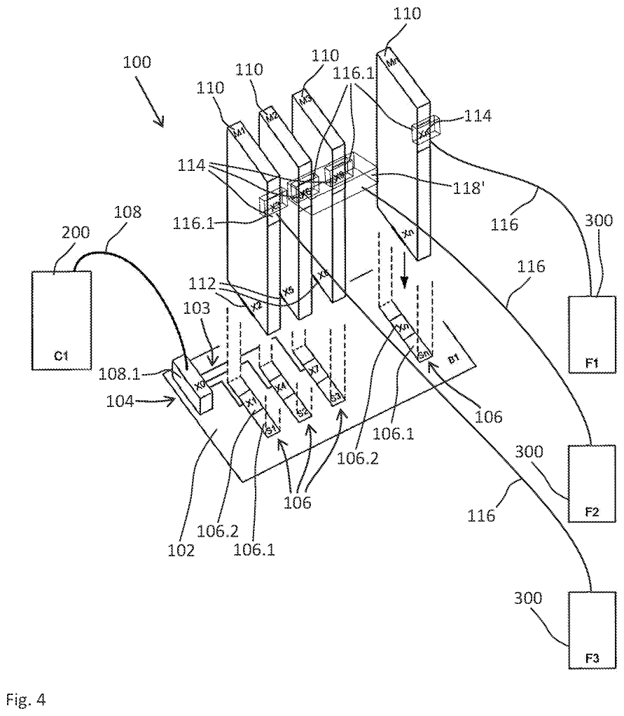

FIG. 4 schematically illustrates a perspective view of a fourth embodiment of the device 100. The fourth embodiment may be implementable by itself or in further development of the first, second and/or third embodiments.

The signal line 116 of one or each field device 300 may comprise a cross-module (or modules-spanning) plug-in connector half 118′ that is simultaneously detachably connected or connectable to the I/O interfaces 114 of at least two modules 110 for connecting 116.1 the signal line 116 of the one of the field devices 300 to the plurality of modules 110. As a result, redundancy, i.e., a redundant wiring of a field device 300 having at least two modules 110 and/or a redundant signal output to an actuator 300 or redundant signal acquisition from a sensor 300, may be predetermined by the cross-module plug-in connector half 118′.

In the fourth embodiment shown in FIG. 4, each of the signal lines 116 of the field device “F2” is connected to two different modules 110 by means of the cross-module plug-in connector half 118′.

Preferably, the slot interfaces 112 of the respective modules 110 are mechanically and electrically connected to adjacent slots 106 of the base 102. That is, the cross-module plug-in connector half 118′ may overlap directly adjacent modules on the base 102.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

Device 100
Base 102
Control interface 104
Slot 106
Mechanical connection 106.1
Electrical connection (or pass or feed-through) 106.2
Line channels 108
Connection of the control 108.1
Module 110
Base-side slot interface 112
Field-side input and/or output interface (I/O interface) 114
Connection of the field device, preferably field connector 116.1
Signal lines 116
Cross-module plug-in connector half of a field device 118
Cross-module plug-in connector half of plurality of field devices 118′
Control system, preferably PLC or microcontroller 200
Field device, preferably sensor and/or actuator 300

1: A device for exchanging signals between a control system and at least two field devices, comprising:
a base comprising a control interface and at least two slots, the control interface being configured to connect to at least two electrical line channels of the control system, and each slot of the at least two slots being configured to detachably mechanically connect to a module and to pass at least one of the line channels of the at least two electrical line channels to a respective module; and
one or more modules, each module of the one or more modules comprising a base-side slot interface and a field-side input and/or output interface, I/O interface, different from the slot interface,
wherein the slot interface is configured to mechanically and electrically detachably connect to one slot of the slots of the base, and
wherein the I/O interface is configured to connect to signal lines of at least one field device of the at least two field devices.

2: The device of claim 1, wherein the base comprises a backplane configured to pass the at least one of the line channels to the respective module.

3: The device of claim 1, wherein the control interface of the base comprises a plug-in connector half configured to connect to the at least two electrical line channels of the control system.

4: The device of claim 1, wherein the I/O interface of one module or each modulo comprises a plug-in connector half configured to connect to the signal lines of a respective field device.

5: The device of claim 1, further comprising:
signal lines of a plurality of field devices,
wherein the signal lines of each field device of the plurality of field devices comprise a plug-in connector half that is detachably connected or connectable to the I/O interface of the respective module for connecting to the signal lines of the respective field device.

6: The device of claim 1, further comprising:
signal lines of a plurality of field devices,
wherein the signal lines of the plurality of field devices comprise a modules-spanning plug-in connector half that is simultaneously detachably connected or connectable to the I/O interfaces of the respective modules for connecting the signal lines of the plurality of field devices.

7: The device of claim 1, further comprising:
signal lines of one field device of the field devices,
wherein the signal lines of the one field device of the field devices comprise a modules-spanning plug-in connector half that is simultaneously detachably connected or connectable to the I/O interfaces of at least two modules for connecting the signal lines of the one of the field devices to the plurality of modules.

8: The device of claim 1, further comprising:
signal lines of at least one field device,
wherein the signal lines of the at least one field device comprise a plug-in connector half that is detachably connected or connectable directly to one of the control interfaces of the base for connecting the signal lines of the respective field device.

9: The device of claim 1, wherein all I/O interfaces are identical in construction and/or all connections of the signal lines are identical in construction.

10: The device of claim 1, wherein the I/O interface and the slot interface of each module are spatially separated from each other.

11: The device of claim 1, wherein the I/O interface and the slot interface of each module are arranged at different edges of a respective module and/or different sides of a module housing of the respective module.

12: The device of claim 1, wherein the base is configured to pass different line channels of the control system at different slots.

13: The device of claim 1, wherein the base is configured to pass one line channel of the line channels of the control system at each of the slots.

14: The device of claim 1, wherein the base is configured to pass a line channel to the respective module without any signal processing of its own and/or with a linear signal response.

15: The device of claim 1, wherein the at least two slots of the base are configured to mechanically connect at least two modules independently of each other to the base and/or to mechanically disconnect at least two modules independently of each other from the base.

16: The device of claim 1, wherein the modulo, or at least one module or each of the modules, comprises a signal processing unit configured to output and/or acquire signals at the I/O interface, receive and/or transmit signals at the slot interface, and process the received signals into the output signals and/or process the acquired signals into the transmitted signals.

17: The device of claim 1, further comprising:
a device housing,
wherein the base is arranged in the device housing, and
wherein the one or more modules are arranged or arrangeable in the device housing when connected to the base.

18: The device of claim 3, wherein the plug-in connector half comprises a socket.

19: The device of claim 4, wherein the plug-in connector half comprises a socket.

20: The device of claim 6, wherein the slot interfaces of the respective modules are mechanically and electrically connected to adjacent slots of the base.
